(19) United States
(12) Patent Application Publication
(10) Pub. No.: US 2025/0357207 A1
(43) Pub. Date: Nov. 20, 2025

(54) METHOD FOR DEPOSITING TUNGSTEN IN HIGH-ASPECT-RATIO STRUCTURE, AND SEMICONDUCTOR SUBSTRATE THEREOF

(71) Applicant: ADVANCED MICRO-FABRICATION EQUIPMENT INC. CHINA, Shanghai (CN)

(72) Inventors: Yufeng ZHUANG, Shanghai (CN); Shuliang LV, Shanghai (CN); Yuan LI, Shanghai (CN); Heng TAO, Shanghai (CN)

(21) Appl. No.: 18/865,647

(22) PCT Filed: Jun. 27, 2023
(86) PCT No.: PCT/CN2023/102755

§ 371 Date: Jul. 11, 2025

(30) Foreign Application Priority Data
Jul. 4, 2022 (CN) 202210786306.9

(51) Int. Cl. H01L 21/768

(52) U.S. Cl. CPC H01L 21/76879; H01L 21/76883

(57) ABSTRACT

Method for depositing tungsten in high-aspect-ratio (>50) structure includes: depositing a tungsten layer with first thickness on side wall and bottom of the recessed structure; introducing treatment gas to the substrate, the treatment gas includes free radical containing fluorine/chlorine and free radical containing one of carbon, sulfur, nitrogen, hydrogen or oxygen; and depositing tungsten layer with second thickness, so that at least part area of the recessed structure is filled with the tungsten. The free radicals in the treatment gas form surface bond on surface of the tungsten layer, so that subsequent deposition of the tungsten can be retarded, the etching with the free radical further prevents premature closing of a top opening of the recessed structure, seams in the recessed structure can be moved downward and narrowed, and can be prevented from being exposed during a subsequent CMP treatment process.

### TECHNICAL FIELD

The present invention relates to the field of semiconductors, and in particular to a method for depositing tungsten in a high-aspect-ratio structure, and a semiconductor substrate thereof.

### BACKGROUND

In the aspects of memory devices, tungsten is mainly applied to word lines and contacts of 3D NAND. The 3D NAND is formed by a multi-layer stack. As the integration of devices increases, the number of stack layers of the 3D NAND also increases, and the size of feature areas used as word lines and contacts is also increasingly reduced. At present, the mainstream number of the stack layers of the 3D NAND is 128, and the corresponding feature area has a high aspect ratio. The reduction in the size of the feature area brings great challenges to the deposition of tungsten in terms of both process and devices.

In the current tungsten deposition process, when a conventional tungsten deposition process is performed in the feature area with a high aspect ratio (>50:1), a tungsten material layer as a seed crystal or a nucleating layer is usually deposited in the feature area first, and then a plurality of tungsten filling layers are successively deposited in the feature area. However, as the feature size of the feature area structure continues to shrink and the number of stack layers continues to increase, it is difficult for existing solutions to ensure the filling effect of the feature area, and there will still be relatively large seams inside the feature area. During the subsequent chemical-mechanical planarization (CMP) process, part of the thickness of the top of the feature area will be worn away. If the seam position inside the feature area is too high, it will be exposed during CMP treatment, and CMP mortar will enter the seam and erode the tungsten filling layers, resulting in the loss of the tungsten filling material, reducing the electrical performance and service life of the entire device, and further increasing the loss of the entire device.

### SUMMARY

An objective of the present invention is to provide a method for depositing tungsten in a high-aspect-ratio structure, and a semiconductor substrate thereof. According to the method, a tungsten material is deposited in a recessed structure with an aspect ratio greater than 50, and the first deposition step, the treatment step and the second deposition step are combined. A tungsten material layer is treated by a treatment gas, and a surface of the tungsten material can be etched through a free radical containing fluorine/chlorine in the treatment gas, so that the size of a top opening of the recessed structure can be increased, thereby facilitating the subsequent filling of the tungsten material. Meanwhile, a radical free at least containing one of carbon, sulfur, nitrogen, hydrogen or oxygen in the treatment gas forms a surface bond on the surface of the tungsten material layer, so that the subsequent deposition of the tungsten material at the position of the surface bond can be retarded, the premature closing of the top opening of the recessed structure is further avoided, seams in the recessed structure can be moved downward and narrowed, and the seams can be prevented from being exposed in the subsequent CMP treatment process, thereby facilitating prolonging the service life of the semiconductor substrate and improving the electrical performance of the semiconductor substrate. On the other hand, according to the method, a new observable thin film layer will not be formed in the tungsten material layer, thereby avoiding the adverse effect on the semiconductor substrate.

To achieve the above objective, the present invention is achieved through the following technical solutions:

a method for depositing tungsten in a high-aspect-ratio structure is provided, the high-aspect-ratio structure is a recessed structure recessed downward from a surface of a substrate, the aspect ratio of the recessed structure is greater than 50:1. The method for depositing the tungsten includes:

a first deposition step: depositing a tungsten material layer with a first thickness on a side wall and at the bottom of the recessed structure, where the first thickness is 10-500 Angstroms;

a treatment step: introducing a treatment gas to the surface of the substrate, where the treatment gas includes a free radical containing fluorine/chlorine and a free radical at least containing one of carbon, sulfur, nitrogen, hydrogen or oxygen, the flow rate range of the treatment gas is 1-200 sccm, and the free radical at least containing one of carbon, sulfur, nitrogen, hydrogen or oxygen and at least part area of the tungsten material layer deposited on the side wall of the recessed structure form a tungsten growth inhibition area; and

a second deposition step: depositing a tungsten material layer with a second thickness in the recessed structure treated in the treatment step, so that at least part area of the recessed structure is filled with the tungsten.

Optionally, the tungsten growth inhibition area includes an area extending from the surface of the substrate to the bottom of the recessed structure along the side wall of the recessed structure by a first depth, where the first depth is less than or equal to ⅔ of the depth of the recessed structure.

Optionally, the treatment gas etches the tungsten material layer with a second depth on a side wall of the top of the recessed structure through the free radical containing fluorine/chlorine, where the second depth is less than or equal to the first depth.

Optionally, the time range of the treatment step is 0-180 seconds.

Optionally, the time range of the treatment step is 0-40 seconds.

Optionally, the tungsten material layer filled in the second deposition step includes a long strip-shaped pore inside, where the height of the long strip-shaped pore is less than 60% of the depth of the recessed structure.

Optionally, the first deposition step adopts an atom-like layer deposition process or a pulse deposition process or a combination of an atom-like layer deposition process/pulse deposition process and a chemical vapor deposition process; and

the second deposition step adopts the chemical vapor deposition process.

Optionally, in the first deposition step, a tungsten nucleation layer or a tungsten nucleation layer and part of a tungsten bulk layer is/are deposited.

Optionally, the method further includes:

repeatedly performing the treatment step and the second deposition step, so that more parts of the recessed structure are filled.

Optionally, the treatment gas flow rate or treatment time in the current treatment step is less than the treatment gas flow rate or treatment time in the previous treatment step.

Optionally, the process time of the current second deposition step is shorter than the process time of the previous second deposition step.

Optionally, the process time of the last second deposition step is longer than the process time of the previous second deposition step.

Optionally, when the treatment step and the second deposition step are performed repeatedly, the method further includes performing the first deposition step after at least one second deposition step.

Optionally, the treatment step includes a plurality of alternating treatment substeps and purification substeps, the treatment gas is introduced into the treatment substeps, and an inert gas is introduced into the purification substeps.

Optionally, the process time of the treatment substeps or the purification substeps is shorter than 60 seconds.

Optionally, the process time of the treatment substeps or the purification substeps is shorter than 10 seconds.

Optionally, the treatment gas is selected from one of SF₆, NF₃, HCl, fluorocarbon, hydrofluorocarbon, oxyfluoride, chlorocarbon, chlorohydrocarbon and oxychloride, or a mixed gas thereof.

Optionally, the treatment step includes a plurality of treatment operations, and the treatment effect of each of the treatment operations is adjustable.

Optionally, the process conditions of the treatment operations are the same;

or the treatment time of each of the treatment operations is gradually reduced and/or the pressure of each of the treatment operations is gradually increased and/or the gas flow rate is gradually reduced.

Optionally, the pressure range of the first deposition step is 1-30 Torr, and the pressure range of the second deposition step is 5-100 Torr.

Optionally, a method for depositing tungsten in a high-aspect-ratio structure is provided, the high-aspect-ratio structure is a recessed structure recessed downward from a surface of a substrate, the aspect ratio of the recessed structure is greater than 50:1. The method for depositing the tungsten includes:

a first deposition step: depositing tungsten nucleation layers on a side wall and at the bottom of the recessed structure;

a treatment step: introducing a treatment gas to the surface of the substrate, where the treatment gas includes a free radical containing fluorine/chlorine and a free radical at least containing one of carbon, sulfur, nitrogen, hydrogen or oxygen, the flow rate range of the treatment gas is 1-200 sccm, and the free radical at least containing one of carbon, sulfur, nitrogen, hydrogen or oxygen and at least part area of the tungsten nucleation layer deposited on the side wall of the recessed structure form a tungsten growth inhibition area; and

a second deposition step: depositing a tungsten material layer in the recessed structure treated in the treatment step, so that at least a part recessed structure is filled with the tungsten.

Optionally, the first deposition step adopts an atom-like layer deposition process and/or a pulse deposition process; and the second deposition step adopts a chemical vapor deposition process.

Optionally, the thickness of the tungsten nucleation layer deposited in the first deposition step is less than 150 Angstroms.

Optionally, the treatment step includes a plurality of alternating treatment substeps and purification substeps, the treatment gas is introduced into the treatment substeps, and an inert gas is introduced into the purification substeps.

Optionally, the time range of the treatment step is 0-30 seconds.

Optionally, the treatment gas is selected from one of SF₆, NF₃, HCl, fluorocarbon, hydrofluorocarbon, oxyfluoride, chlorocarbon, chlorohydrocarbon and oxychloride, or a mixed gas thereof.

Optionally, the method further includes: repeatedly performing the treatment step and the second deposition step, so that more parts of the recessed structure are filled.

Optionally, the treatment gas flow rate or treatment time in the current treatment step is less than or shorter than the treatment gas flow rate or treatment time in the previous treatment step; and/or the process time of the current second deposition step is shorter than the process time of the previous second deposition step.

Optionally, the process time of the last second deposition step is longer than the process time of the previous second deposition step.

Optionally, when the treatment step and the second deposition step are performed repeatedly, the method further includes performing the first deposition step after at least one second deposition step.

Optionally, a semiconductor substrate is provided. The semiconductor substrate includes a material layer on a surface.

A recessed structure with an aspect ratio greater than 50 is arranged on the material layer, a side wall and a bottom wall of the recessed structure comprise barrier layers, the internal space of the recessed structure surrounded by the barrier layers is filled with a tungsten material layer from the bottom to the top so as to form a low-resistance path from the bottom of the recessed structure to the top of the recessed structure, and the tungsten material layer is prepared by the method for depositing tungsten in a high-aspect-ratio structure.

Optionally, a plurality of seams that are mutually separated and distributed up and down are formed inside the tungsten material layer, and the height of each of the seams is less than ¼ of the height of the recessed structure.

Optionally, a semiconductor substrate is provided. The semiconductor substrate includes a material layer on a surface. A recessed structure with an aspect ratio greater than 50 is arranged on the material layer, a side wall and a bottom wall of the recessed structure comprise barrier layers, the internal space of the recessed structure surrounded by the barrier layers is filled with a tungsten material layer from the bottom to the top so as to form a low-resistance path from the bottom of the recessed structure to the top of the recessed structure, a plurality of scams that are mutually separated and distributed up and down are formed inside the tungsten material layer, and the height of each of the seams is less than ¼ of the height of the recessed structure.

Compared with the prior art, the present invention has the following advantages:

in the method for depositing the tungsten in the high-aspect-ratio structure, and the semiconductor substrate thereof according to the present invention, the tungsten material is deposited in the recessed structure with the aspect ratio greater than 50, the method combines the first deposition step, the treatment step and the second deposition step, the tungsten material layer formed in the first deposition step is treated by the treatment gas in the treatment step, and the surface of the tungsten material layer can be etched by the free radical containing fluorine/chlorine in the treatment gas, so that the size of the top opening of the recessed structure can be increased, and the subsequent filling of the tungsten material can be facilitated; meanwhile, the free radical at least containing one of carbon, sulfur, nitrogen, hydrogen or oxygen in the treatment gas forms the surface bond on the surface of the tungsten material layer close to the opening of the recessed structure, the area where the surface bond is formed will delay the growth of the tungsten material layer in the second deposition step, the tungsten growth inhibition area is formed on the side wall of the recessed structure, the depth of the active free radical entering the recessed structure can be controlled by controlling the flow rate range of the treatment gas in the treatment step to 1-200 sccm, and then the depth of the tungsten growth inhibition area can be controlled. The premature closing of a top opening of the recessed structure is further avoided, seams in the recessed structure can be moved downward and narrowed, and the seams can be prevented from being exposed during a subsequent CMP treatment process, thereby facilitating prolonging the service life of the semiconductor substrate and improving the electrical performance of the semiconductor substrate, and minimizing the power loss and overheating in the integrated circuit design. On the other hand, according to the method, a new observable thin film layer will not be formed in the tungsten material layer, thereby avoiding the adverse effect on the semiconductor substrate.

Further, the treatment step in the method can act on the tungsten nucleation layer, so that the tungsten bulk layer tends to be deposited on a middle lower part of the internal space of the recessed structure subsequently, thereby further ensuring the downward movement and narrowing of the seams in the recessed structure.

Further, the method adopts a mode of performing the plurality of steps repeatedly, so that a tungsten section is filled and grown in the recessed structure, a large seam in the recessed structure is divided into a plurality of small seams, and the seams can be further moved downward in the recessed structure, thereby preventing the seams from being exposed in the subsequent CMP treatment process, and preventing the tungsten material layer in the recessed structure from being eroded.

### BRIEF DESCRIPTION OF THE DRAWINGS

FIG. 1 is a partial schematic structural diagram of a semiconductor substrate according to the present invention;

FIG. 2 is a schematic diagram of a method for depositing tungsten in a high-aspect-ratio structure according to the present invention;

FIG. 3 is a schematic diagram of a tungsten deposition processing performing one treatment step according to the present invention;

FIG. 4 is a schematic diagram of a tungsten deposition processing performing one treatment step according to another embodiment;

FIG. 5 and FIG. 6 are schematic diagrams of a tungsten deposition process performing a plurality of treatment steps according to the present invention; and

FIG. 7 is a schematic diagram of a method for depositing tungsten in a high-aspect-ratio structure according to another embodiment.

### DETAILED DESCRIPTION OF THE EMBODIMENTS

To make objectives, technical solutions and advantages of the embodiments of the present invention clearer, the technical solutions in the embodiments of the present invention will be clearly and completely described below in conjunction with the drawings of the embodiments of the present invention. Obviously, the described embodiments are part of, but not all of, the embodiments of the present invention. Based on the embodiments of the present invention, all other embodiments obtained by those of ordinary skill in the art without creative work are included in the protection scope of the present invention.

It should be noted that in the specification, the terms “including”, “comprising”, “having” or any other variants thereof are intended to cover non-exclusive inclusion, so that a process, method, article or terminal device including a series of elements not only include those elements, but also include other elements not explicitly listed, or elements inherent to such process, method, article or terminal device. In absence of more limitations, an element defined by “including” or “comprising” does not exclude the existence of other elements in the process, method, article, or terminal device that includes the element.

It should be noted that the accompanying drawings all adopt very simplified forms and use inaccurate ratio, which are only used for conveniently and clearly assisting in describing the objective of one embodiment of the present invention.

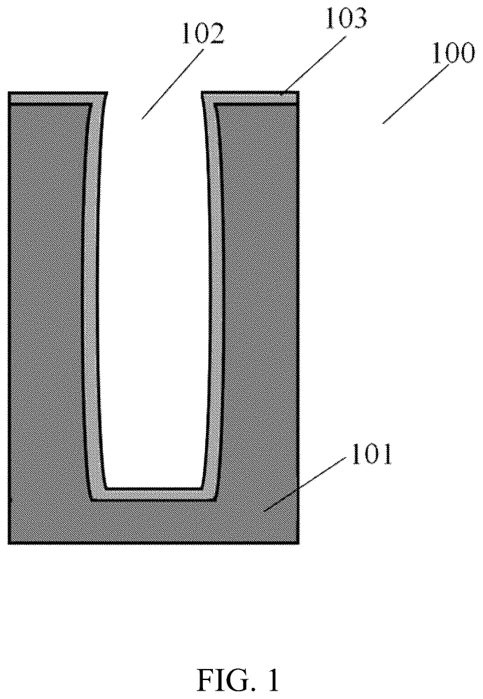

As shown in FIG. 1, it is a partial schematic diagram of a semiconductor substrate 100 according to the present invention. The semiconductor substrate 100 includes a material layer 101 (such as silicon oxide) on a surface; a plurality of recessed structures 102, that is, feature areas, with an aspect ratio greater than 50 are arranged on the material layer 101; each of the recessed structures 102 may be a pore-shaped structure or a groove-shaped structure; and side walls and bottom walls of the recessed structures 102 include barrier layers 103, for example, titanium nitride (TiN) layers. The internal space surrounded by the barrier layers 103 is required to be filled with the tungsten material layer from bottom to top so as to form a low-resistance path from the bottom of the recessed structure 102 to the top of the recessed structure 102. However, with the increasing improvement of technology nodes, higher requirements are put forward for the deposition process of the tungsten material layer in the recessed structure 102 with a high aspect ratio.

In the tungsten deposition process, during deposition, compared with the bottom in the recessed structure 102, more tungsten materials will be deposited close to the top opening of the recessed structure 102 to form overhangs at the top opening. With the progress of the deposition process, the overhangs gradually grow, resulting in the premature closing of the top opening of the recessed structure 102 and a large seam inside the recessed structure 102. Therefore, to ensure the deposition effect of the tungsten material layer, the recessed structure 102 may be inhibited by a conformal inhibition treatment process, thereby preventing the top opening area of the recessed structure 102 from being pinched off in the subsequent deposition process. However, the conformal inhibition treatment process will also introduce a high-resistance layer with a certain thickness, and the high-resistance layer can be identified and detected, so that the electrical conductivity of the tungsten material layer is greatly affected, and a low-resistance path cannot be formed on the semiconductor substrate 100, thereby increasing the loss of devices.

To ensure good electric performance and service life of the semiconductor substrate 100, the present invention provides a method for depositing tungsten in a high-aspect-ratio structure. The high-aspect-ratio structure is a recessed structure 102 recessed downward from a surface of the substrate, and the aspect ratio of the recessed structure 102 is greater than 50:1. The method provided by the present invention also has a good effect on the recessed structure with the aspect ratio less than 50:1. Undesirable seams 205 or pores are easier to appear inside the recessed structure 102 with the aspect ratio greater than 50:1 during tungsten deposition, so the present invention takes the recessed structure 102 with the aspect ratio greater than 50:1 as an example for description.

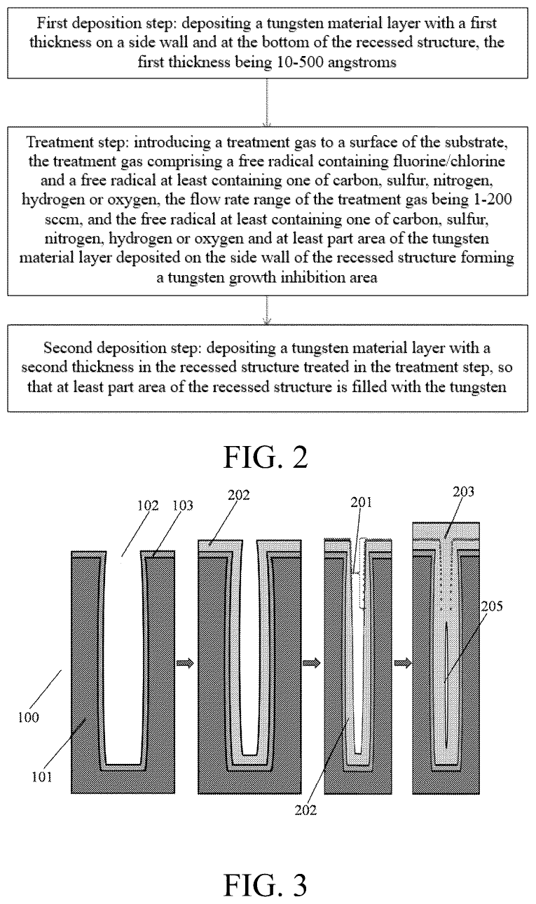

As shown in FIG. 2 to FIG. 7, the method for depositing the tungsten in the high-aspect-ratio structure provided by the present invention includes: a first deposition step: depositing a tungsten material layer with a first thickness on a side wall and at the bottom of the recessed structure 102, where the first thickness is 10-500 Angstroms; a treatment step: introducing a treatment gas to a surface of the substrate, where the treatment gas includes a free radical containing fluorine/chlorine and a free radical at least containing one of carbon, sulfur, nitrogen, hydrogen or oxygen, the flow rate range of the treatment gas is 1-200 sccm, and the free radical at least containing one of carbon, sulfur, nitrogen, hydrogen or oxygen and at least part area of the tungsten material layer deposited on the side wall of the recessed structure 102 form a tungsten growth inhibition area 201; and a second deposition step: depositing a tungsten material layer with a second thickness in the recessed structure 102 treated in the treatment step, so that at least part area of the recessed structure 102 is filled with the tungsten.

It can be seen from the above that according to the method for depositing the tungsten in the high-aspect-ratio structure provided by the present invention, one tungsten material layer is deposited in the recessed structure 102 (on the barrier layer 103) first, and then the treatment gas is introduced to treat the surface of the tungsten material layer, where the tungsten material of the top opening area of the recessed structure 102 can be etched by the free radical containing fluorine/chlorine in the treatment gas to enlarge the size of the top opening area, thereby preventing the premature closing of the interior of the recessed structure 102 in the subsequent process; meanwhile, a surface bond can be formed on the surface of the tungsten material layer trough the free radical at least containing one of carbon, sulfur, nitrogen, hydrogen or oxygen in the treatment gas, the area where the surface bond is formed will delay the growth of the tungsten material layer in the second deposition step, a tungsten material layer deposition delay area, that is, a tungsten growth inhibition area 201 (a point-point area on the side wall of the recessed structure 102 in FIG. 3), is formed on the side wall of the recessed structure 102, the depth of the free radical at least containing one of carbon, sulfur, nitrogen, hydrogen or oxygen entering the recessed structure 102 can be controlled by controlling the flow rate range of the treatment gas and the introducing time of the treatment gas in the treatment step, and then the depth of the tungsten growth inhibition area 201 can be controlled. The presence of the surface bond will delay/inhibit the subsequent deposition of the tungsten material layer at the position, but a new observable thin film is not formed, so that the electrical performance of the semiconductor substrate 100 will not be affected. The flow rate range of the treatment gas provided by the present invention is 1-200 sccm. Under the conditions that the pressure inside the chamber is unchanged and the flow rate of other inert gases in the chamber is also unchanged, the flow rate of the treatment gas can be controlled to control the concentration of the treatment gas at the top of the recessed structure 102, and then the diffusion rate of the treatment gas in the recessed structure 102 can be controlled. Due to the low flow rate of the treatment gas in the treatment step of the present invention and the short introducing time, such as 0-180 seconds, the free radical at least containing one of carbon, sulfur, nitrogen, hydrogen or oxygen is diffused into the recessed structure 102 to a limited depth, and only a tungsten growth inhibition area 201 is formed on the side wall of the recessed structure 102 with the opening downward for a certain distance. The deposition of the tungsten material layer at the top opening area of the recessed structure 102 and the side wall area of the recessed structure 102 close to the top opening to a certain depth in the second deposition step is delayed by controlling the flow rate and time of the treatment gas, and the tungsten material layer is preferentially deposited on the middle lower part in the recessed structure 102 other than the tungsten growth inhibition area 201, so that the closing time of the opening of the recessed structure 102 is delayed, and the height of the seams 205 in the recessed structure 102 is reduced. Meanwhile, the seams 205 can be moved downward (located on the middle lower part of the recessed structure 102), so that the risk that the seams 205 are exposed prematurely in the CMP process and then attacked by mortar can be reduced, the service life of the semiconductor substrate 100 can be prolonged, and a good low-resistance path can be ensured.

As shown in FIG. 3, the tungsten growth inhibition area 201 includes an area extending from the surface of the semiconductor substrate 100 to the bottom of the recessed structure 102 along the side wall of the recessed structure 102 by a first depth, and at least part area of the surface of the top of the semiconductor substrate 100. Optionally, the first depth is less than or equal to 2/3 of the depth of the recessed structure 102.

Due to the steric effect of gas diffusion and the characteristic of the free radical, various free radicals in the treatment gas are not easy to enter the small-size recessed structure 102, and the etching effect of the free radical containing fluorine/chlorine and the density of the surface bonded formed by the free radical at least containing one of carbon, sulfur, nitrogen, hydrogen or oxygen on the tungsten material layer with the first thickness will be gradually reduced from the top of the recessed structure 102 downward. Therefore, the tungsten material layer at the top area of the recessed structure 102 is most obviously affected by the treatment gas in the treatment step. Since the tungsten deposition of the tungsten material layer in the top area is most obviously inhibited by the surface bond, in the subsequent tungsten deposition process, the tungsten deposition in the top area will be delayed most obviously, so that the tungsten material will be preferentially deposited in the bottom area in the recessed structure 102.

In the practical application, the component diffusion can be regulated and controlled according to the difference of each component in the treatment gas as required. For example, the component content of the free radical at least containing one of carbon, sulfur, nitrogen, hydrogen or oxygen in the treatment gas can be increased, so that the free radical at least containing one of carbon, sulfur, nitrogen, hydrogen or oxygen can passivate the tungsten material layer with the first depth on the side wall of the recessed structure 102. The treatment gas etches the tungsten material layer with the second depth on a side wall of the top of the recessed structure 102 by the free radical containing fluorine/chlorine. The second depth is less than the first depth, that is, the range of the tungsten growth inhibition area 201 is larger than the range of the etching area, so that the tungsten can be preferentially deposited on the middle lower part of the recessed structure 102 subsequently, thereby further ensuring the narrowing and downward movement of the seams 205 in the recessed structure 102. Of course, each gas component in the treatment gas can be adjusted, so that the second depth is equal to the first depth.

As shown in FIG. 3, in this embodiment, the tungsten material layer with the first thickness deposited in the first deposition step is a tungsten nucleation layer 202, and the tungsten material layer with the second thickness deposited in the second deposition step is a tungsten bulk layer 203. The tungsten nucleation layer 202 deposited in the first deposition step is etched by the treatment gas, with the etching thickness less than the first thickness of the tungsten nucleation layer 202, and the tungsten growth inhibition area 201 is formed on the surface of the tungsten nucleation layer 202 at the top of the recessed structure 102, so that the subsequent deposition of the tungsten bulk layer 203 at the top of the recessed structure 102 can be inhibited, thereby avoiding the premature closing of the opening of the recessed structure 102 and preventing the deposition path of the tungsten material of the recessed structure 102 from being pinched off. Meanwhile, the tungsten growth inhibition area 201 does not form a new observable thin film and has little influence on the electrical performance in the recessed structure 102, thereby ensuring good performance of semiconductor devices.

Optionally, the first deposition step adopts an atom-like layer deposition process and/or a pulse deposition process; and the second deposition step adopts a chemical vapor deposition (CVD) process. That is, the tungsten nucleation layer 202 and the tungsten bulk layer 203 adopt different deposition processes. Optionally, the two can be performed in the same chamber.

Specifically, in the atom-like layer deposition process, one or more reductants, purge gases, tungsten-containing precursors and purge gases are sequentially introduced into the chamber, and the process is repeated periodically until the required thickness is obtained, so that the tungsten nucleation layer 202 is formed through the atom-like layer deposition process, that is, a thin conformal nucleation layer deposited subsequently. The tungsten nucleation layer 202 formed by the method has high compactness and small surface roughness, and facilitates the surface flatness of the subsequent deposition of the tungsten material layer, thereby forming a low-resistivity tungsten film 204. In the pulse deposition process, one or more of reductants and tungsten-containing precursors are introduced into the chamber at the same time, then a purge gas is introduced, and the process is repeated periodically until the tungsten nucleation layer 202 with the required thickness is obtained.

It should be noted that the processes of the atom-like layer deposition process and the pulse deposition process are not limited to the above, and can be adjusted according to the actual process conditions or application requirements, which will not limited by the present invention. Exemplarily, the process of the atom-like layer deposition process in a certain embodiment includes: S1. introducing B₂H₆/SiH₄ (reductant 1)+H₂ (reductant 2); S2. introducing an inert gas for purging; S3. introducing a tungsten-containing precursor+H₂ (reductant 2); S4. introducing an inert gas for purging; and repeating the steps S1-S4. In this embodiment, compared with the reductant 1, the reductant 2 has the reaction activity with the tungsten-containing precursor weaker than the reaction activity of the reductant 1 with the tungsten-containing precursor, so that the diffusion time of the tungsten-containing precursor is prolonged, and the tungsten-containing precursor is distributed above the semiconductor substrate 100 more uniformly. Optionally, the actual deposition rate of the atom-like layer deposition process is adjusted to be greater than the deposition rate of the ordinary atom layer deposition, thereby increasing the deposition rate of the tungsten nucleation layer 202. In practical application, an appropriate deposition process can be selected in the first deposition step according to the process requirements and device conditions, thereby forming the tungsten nucleation layer 202 meeting the actual requirement.

Optionally, in the first deposition step, the process pressure range is 1-30 Torr, the process temperature range is 300° C.-400° C., and the thickness of the tungsten nucleation layer 202 is less than 150 Angstroms. For the tungsten material deposition in the high-aspect-ratio structure, it is not suitable to deposit an excessively thick material in the initial stage, otherwise it is equivalent to that the size of the top opening of the recessed structure 102 is reduced, thereby affecting the gas diffusion during the subsequent deposition and affecting the filling effect of the recessed structure 102. If the tungsten nucleation layer 202 is deposited by the atom-like layer deposition process, the single circulation time is long, the reaction of switching the deposition rate is slow, the thickness of the initially deposited tungsten nucleation layer 202 will directly affect the filling speed of the tungsten material in the whole recessed structure 102, thereby affecting the throughput of a treatment device treating the semiconductor substrate 100. Therefore, the film thickness of the tungsten material deposited in the initial state is very important. In this embodiment, the tungsten nucleation layer 202 formed in the first deposition step is about 100 Angstroms.

After the first deposition step is completed, the treatment gas is introduced, and the treatment gas is dissociated by a remote plasma device to perform surface treatment on the tungsten nucleation layer 202. During the treatment step, the tungsten nucleation layer 202 is etched by the free radical containing fluorine/chlorine in the treatment gas, and the etching thickness is less than the thickness of the previous tungsten nucleation layer 202. On the other hand, the tungsten bulk layer 203 cannot be directly deposited on the barrier layer 103 of the semiconductor substrate 100, the tungsten nucleation layer 202 is required to be deposited first, some suspending bonds are present on the surface of the tungsten nucleation layer 202, and these suspending bonds usually can make the tungsten bulk layer 203 better attached to the tungsten nucleation layer 202 to facilitate the subsequent growth of the tungsten material. In the treatment step of the present invention, the free radical at least containing one of carbon, sulfur, nitrogen, hydrogen or oxygen in the treatment gas is bonded with the suspending bonds in the tungsten growth inhibition area 201 on the surface of the tungsten nucleation layer 202 to form a surface bond, so that the tungsten bulk layer 203 cannot be bonded with the suspending bonds of the tungsten nucleation layer 202 in the area, thereby delaying the subsequent deposition of the tungsten bulk layer 203 at the position. If it is necessary to continuously grow the tungsten material in the tungsten growth inhibition area 201, it is necessary to form a suspending bond again at the position. For example, when the tungsten bulk layer 203 is deposited by the chemical vapor deposition process in the subsequent second deposition step, it takes a certain reaction time to form the suspending bond again at the position to facilitate the subsequent deposition of the tungsten bulk layer 203; however, the tungsten bulk layer 203 is normally deposited in an area other than the tungsten growth inhibition area 201 within the reaction time; therefore, from the view of the tungsten material deposition of the whole recessed structure 102, the treatment gas will cause the tungsten growth delay of tens of seconds or even thousands of seconds in the tungsten growth inhibition area 201 (the delay time is determined by the treatment intensity of the treatment gas and the specific process of the subsequent deposition of the tungsten material).

Optionally, in the treatment step, the flow rate range of the treatment gas is 1-200 sccm, the process pressure range is 1-30 Torr, the process temperature range is 300° C.-400° C., and the process time range is 0-40 seconds. It should be noted that the above parameters are not limited by the present invention and can be regulated and controlled according to the actual requirement to achieve the optimal treatment effect. For example, in another embodiment, the time range of the treatment step is 0-30 seconds, so that the treatment intensity of the treatment gas can be adjusted. Further optionally, the treatment gas includes, but is not limited to one of SF₆, NF₃, HCl, fluorocarbon (such as CF₄, CHF₃ and C₂F₄), hydrofluorocarbon, oxyfluoride, chlorocarbon, chlorohydrocarbon and oxychloride, or a mixed gas thereof. That is, the treatment gas is a gas containing fluorine/chlorine and at least containing one of carbon, sulfur, nitrogen, hydrogen or oxygen, or a gasified precursor.

After the treatment step is completed, the second deposition step is performed. In this embodiment, the tungsten bulk layer 203 is deposited by the chemical vapor deposition process. One or more reductants and tungsten-containing precursors are introduced in a chamber. Through the chemical vapor deposition process, the reductants and the tungsten-containing precursors deposit the tungsten bulk layer 203 with a second thickness on the tungsten nucleation layer 202 treated by the treatment gas. Due to the treatment of the free radical at least containing one of carbon, sulfur, nitrogen, hydrogen or oxygen in the treatment gas in the treatment step, the tungsten growth inhibition area 201 is formed on a surface of a side wall with a certain depth downward from the top opening of the recessed structure 102, and the tungsten material in the second deposition step is preferentially deposited on the surface of the tungsten nucleation layer 202 on the middle lower part of the recessed structure 102, so that the seams 205 in the recessed structure 102 can be moved downward and narrowed. Optionally, the tungsten-containing precursors adopt tungsten hexafluoride (WF₆), and the reductants adopt hydrogen (H₂). Of course, the types of the tungsten-containing precursors and the reductants are not limited to the above, and other reagents may be used, as long as the same deposition effect can be achieved. For example, the tungsten-containing precursors adopt WC₁₆, and the reductants adopt silane, diborane and the like. Optionally, the pressure range of the second deposition step is 5-100 Torr, and the process temperature range is 300° C.-400° C.

After the second deposition step is completed, the tungsten material layer filled in the second deposition step includes a long strip-shaped pore inside, and the height of the long strip-shaped pore is less than 60% of the depth of the recessed structure 102, that is, the bottom of the recessed structure 102 is filled with the tungsten material layer. According to the present invention, the treatment step is set between the first deposition step and the second deposition step, the tungsten material layer at the opening is etched by the free radical containing fluorine/chlorine in the treatment gas after a thin tungsten material layer is deposited in the first deposition step, and the free radical at least containing one of carbon, sulfur, nitrogen, hydrogen or oxygen in the treatment gas forms the tungsten growth inhibition area 201 on the surface of the tungsten material layer deposited on the side wall of the recessed structure 102 close to the opening, so the growth of the tungsten material layer of the recessed structure 102 close to the opening area is delayed, thereby ensuring that more deposited gases in the second deposition step enter the bottom of the recessed structure 102 with high aspect ratio to grow the tungsten material layer. Although the elimination of the long strip-shaped pore in the tungsten material layer cannot be ensured completely, the length of the long strip-shaped pore in the recessed structure 102 can be reduced. The closing time of the opening of the recessed structure 102 is retarded, so that the upper end of the formed long strip-shaped pore is as close as possible to the bottom of the recessed structure 102, thereby avoiding the exposure of the long strip-shaped pore during chemical mechanical polarization (CMP) treatment on the surface of the semiconductor substrate 100, and improving the performance of the semiconductor substrate 100.

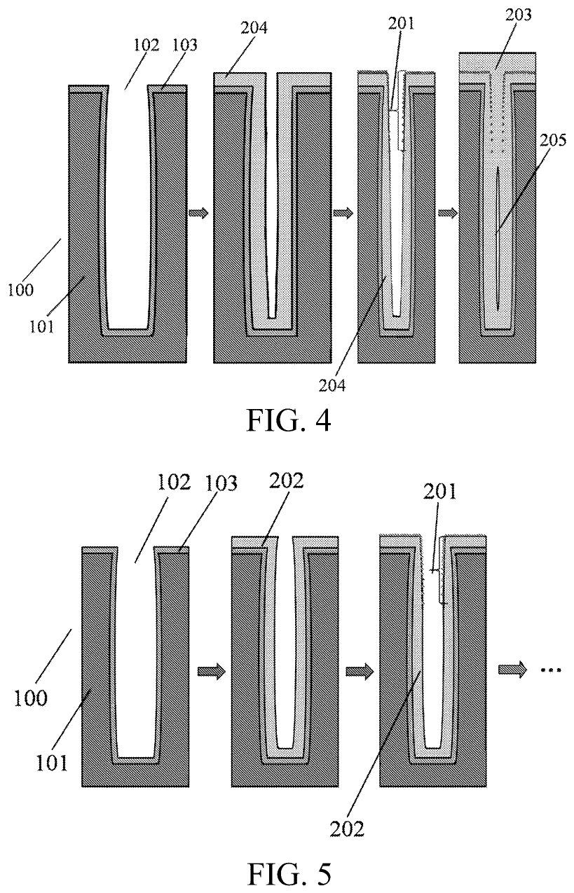

Of course, the types of each tungsten material layer are not limited to the above, and may adopt other composition modes. For example, in another embodiment, as shown in FIG. 4, the tungsten material layer deposited in the first deposition step is a tungsten nucleation layer and a part of a tungsten bulk layer (also referred to as a tungsten film 204), that is, one layer of tungsten film 204 is formed first, and the treatment step is performed on the tungsten bulk layer of the tungsten film 204 to form the tungsten growth inhibition area 201, thereby implementing the surface treatment operation and preventing the subsequent tungsten deposition path from being pinched off too early. After the tungsten film 204 is subjected to surface treatment, the subsequent deposition of the tungsten material layer is continuously performed, so that a small scam 205 is formed in the recessed structure 102, and the erosion of the tungsten material caused by the exposure of the seam 205 during the subsequent CMP treatment can be avoided. Optionally, in the first deposition step in this embodiment, the tungsten film 204 can be deposited by an atom-like layer deposition process or a pulse deposition process or a combination of an atom-like layer deposition process/pulse deposition process and a chemical vapor deposition process, and the specific steps of various processes may be referenced to the above, which will not be elaborated herein. Further optionally, the thickness range of the tungsten film 204 deposited in the first deposition step in this embodiment is 10-500 Angstroms, where the deposition process temperature range of the tungsten nucleation layer 202 is 300° C.-400° C., and the process pressure range is 5-100 Torr; and the etching thickness of the treatment gas in the treatment step in this embodiment is less than the thickness of the previous layer of tungsten film 204.

In practical application, the number of the treatment steps in the tungsten deposition process is not limited by the present invention. In the embodiment shown in FIG. 3, in the tungsten deposition process, only one treatment step is performed, and the recessed structure 102 is completely filled in the following second deposition step.

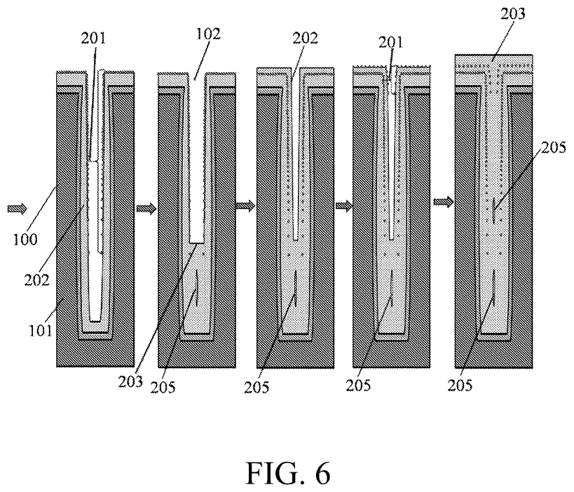

Of course, the tungsten deposition process may adopt a plurality of treatment steps, for example, two treatment steps are performed. As shown in FIG. 5 and FIG. 6, the method for depositing the tungsten in the high-aspect-ratio structure according to the present invention further includes: the treatment step and the second deposition step are repeatedly performed, so that more parts of the recessed structure 102 are filled. Optionally, the etching thickness in each treatment step is less than the thickness of the remaining tungsten nucleation layer 202 and/or the thickness of the tungsten bulk layer 203. The tungsten material layer in the top area of the recessed structure 102 can be continuously treated through the plurality of treatment steps. In the tungsten deposition step after the treatment step, a large seam 205 in the recessed structure 102 is divided into a plurality of small seams 205, the tungsten material still tends to be deposited on the middle lower part of the recessed structure 102 instead of being deposited in the top area of the recessed structure 102, thereby further ensuring the downward movement and narrowing of the seams 205 in the recessed structure 102 and improving the precision of controlling the distribution of the seams 205. Optionally, the process time of the current second deposition step is shorter than the process time of the previous second deposition step, that is, segmented growth intensity of the tungsten material layer is sequentially reduced, so that the seams 205 in the deposition process are reduced. Optionally, the remaining structure will be filled at least, so the process time of the current second deposition step may be longer than the process time of the previous second deposition step.

It can be seen from the above that some suspending bonds are present on the surface of the tungsten nucleation layer 202, and these suspending bonds can promote the tungsten bulk layer 203 to be better attached to the surface of the tungsten nucleation layer 202, thereby facilitating the subsequent growth of the tungsten material. Therefore, to facilitate the subsequent deposition of the tungsten bulk layer 203, one tungsten bulk layer 202 may be deposited after the treatment step and the second deposition step (referring to FIG. 5 and FIG. 6). That is, when the plurality of treatment steps and second deposition steps are performed, the first deposition step is further included after at least one second deposition step, and one tungsten nucleation layer 202 is deposited before the treatment step, so that the tungsten bulk layer 203 can be better attached to the interior of the recessed structure 102 subsequently.

Of course, according to the actual process environment and the product requirements, the method may be repeated many times for filling, that is, the first deposition step, the treatment step and the second deposition step are circulated to implement the segmented growth of the tungsten material layer in the recessed structure 102. The first cycle is to growth one layer of tungsten film 204 at the bottom and on the side wall of the recessed structure 102, the second cycle is to grow the tungsten film 204 on the middle lower part of the recessed structure 102, and the operation is continued until the N^{th} cycle to grow the layer of tungsten film 204 at the top of the recessed structure 102, the large seam 205 in the recessed structure 102 is divided into a plurality of small scams 205, and the seams 205 can be further moved downward in the recessed structure 102, so that the seams 205 can be prevented from being exposed in the subsequent CMP treatment process, and the tungsten material layer in the recessed structure 102 can be prevented from being eroded. It can be predicted that the more times the above method is repeated, the smaller the seams 205 inside the tungsten material layer in the recessed structure 102, and the smaller the performance loss of devices.

Repeating the treatment steps and the second deposition steps for many times can solve the problem in the single deposition step that it is difficult to give consideration to the filling effect of the top and the bottom. When the aspect ratio of the recessed structure 102 is higher, the phenomenon that the bottom is filled but the top has a larger hole or seam 205, or the filling effect of the top is better but the bottom has the seam 205 is more likely to occur. Multiple treatments can give good consideration to the filling effect of each depth in the recessed structure 102. By optimizing the process of each repeated step, the internal seam 205 can be effectively narrowed, and the seam 205 can be controlled to be generated close to the bottom of the recessed structure 102.

Optionally, in the process of performing the treatment steps for many times, the treatment intensities of the treatment steps are gradually weakened (which can be implemented by increasing the process pressure and/or reducing the treatment time and/or reducing the flow rate of the treatment gas), thereby reducing the influence of the treatment steps on the tungsten deposition process while ensuring that downward movement and narrowing of the seams 205 in the recessed structure 102. Exemplarily, the process conditions of the first treatment step are 300° C., 5 Torr, 10 sccm and 30 seconds; and the process conditions of the second treatment step are 300° C., 5 Torr, 10 sccm and 15 seconds.

In practical application, the depth range of the tungsten growth inhibition area 201 generated in the treatment step extending on the side wall of the recessed structure 102 affects the deposition position of the tungsten material in the subsequent second deposition step. Therefore, the position of the subsequent tungsten material deposition can be regulated and controlled by regulating and controlling the depth range of the tungsten growth inhibition area 201 in the treatment step. In terms of gas diffusion, when the flow rate of the treatment gas is small and the treatment time is short, the treatment gas will not be diffused to the middle lower part of the recessed structure 102, but is preferentially diffused to the top of the recessed structure 102 and the side wall close to the top. However, if the flow rate of the treatment gas is small and the treatment time is short, the total amount of the treatment gas will be small, the free radical at least containing one of carbon, sulfur, nitrogen, hydrogen or oxygen in the treatment gas may not saturate the surface of the tungsten material layer deposited in the first deposition step, that is, the free radical at least containing one of carbon, sulfur, nitrogen, hydrogen or oxygen in the treatment gas cannot be bonded with all the suspending bonds in the top area. At this time, the treatment intensity of the treatment gas is weakened, resulting in the weakening of the delay effect of the tungsten growth inhibition area 201. For example, the original delay of the tungsten material layer by tens of seconds may be reduced to the growth of the tungsten material layer within ten seconds, thereby causing the premature closing of the top opening of the recessed structure 102.

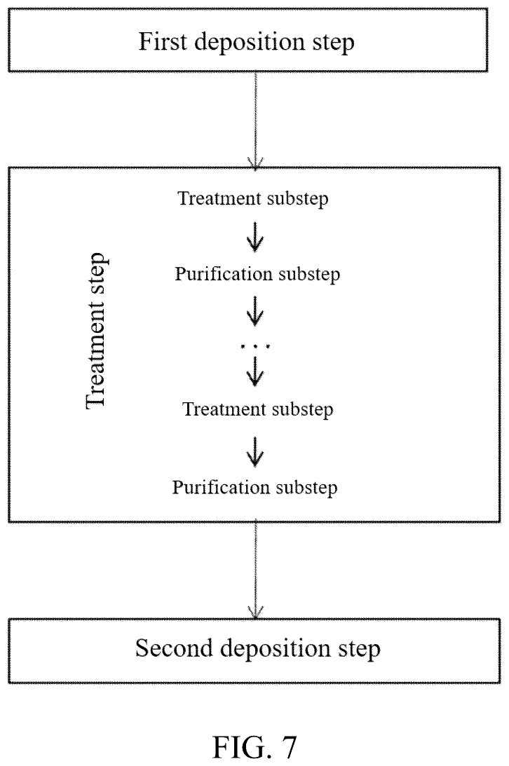

Based on the above factors, as shown in FIG. 7, the treatment step of the present invention includes a plurality of alternating treatment substeps and purification substeps. In the treatment substep, the treatment gas is introduced for surface treatment; and in the purification substep, the inert gas is introduced for purification. The objective of purification is to remove the treatment gas introduced in the treatment substep in time, thereby avoiding the excessive depth of the treatment gas entering the recessed structure 102. The treatment intensity of the top of the recessed structure 102 can be enhanced by controlling the treatment depth of each treatment substep and superposing the times of each substep, so that the premature closing of the top opening of the recessed structure 102 can be avoided. On the other hand, each substep can be adjusted according to the actual characteristic of the recessed structure 102 to implement gradient treatment on the side wall of the top opening of the recessed structure 102, that is the treatment effects of the side wall at different depth positions are different.

Optionally, the process time of the treatment substep or the purification substep is shorter than 60 seconds. Of course, the action time of the two substeps is not limited to the above, and can be adjusted according to the actual process requirement, which will not be limited by the present invention. For example, the process time of the treatment substep or the purification substep is shorter than 10 seconds. Further optionally, the inert gas may adopt Ar, but of course, may adopt other gases that do not affect the reaction.

Further, the treatment process of the treatment step in the present invention may also be implemented by combining a plurality of treatment operations, and the treatment effect of each of the treatment operations can be adjusted to achieve different treatment effects. The tungsten material layer is not deposited between the treatment operations, and the plurality of treatment operations are combined to implement one complete treatment step, so that the treatment effect on the surface of the previous tungsten material layer is enhanced, but the treatment depth of the tungsten material layer in the recessed structure 102 will not be increased. On the other hand, the treatment effect varying with the depth gradient can also be achieved on the surface of the previous tungsten material layer by regulating and controlling each treatment operation, thereby improving the filling effect of the tungsten material. Optionally, each of the treatment operations includes one treatment substep and one purification substep, so that the action intensity of the treatment gas can be further refined, and the treatment effect can be accurately regulated and controlled.

Optionally, the process conditions of the treatment operations are the same. For example, the process condition of the first treatment operation are: 300° C., 5 Torr, 10 sccm and 10 seconds, and then Ar purging is performed; the process conditions of the second treatment operation are: 300° C., 5 Torr, 10 sccm and 10 seconds, and then Ar purging is performed; . . . ; and the process conditions of the Nth treatment operation are: 300° C., 5 Torr, 10 sccm and 10 seconds, and then Ar purging is performed. In the plurality of treatment operations with the same process condition, the diffusion area of the treatment gas in each of the treatment operations is approximately the same, and the subsequent treatment operation can further enhance the treatment effect of the previous treatment operation. For example, when the total amount of the treatment gas in the first treatment operation is too small, the free radical at least containing one of carbon, sulfur, nitrogen, hydrogen or oxygen is unsaturated, not all the suspending bonds on the surface of the tungsten material layer in the top area of the side wall of the recessed structure 102 are bonded with the free radical at least containing carbon, sulfur, nitrogen, hydrogen or oxygen, and the treatment gas in the subsequent treatment operation can further be bonded with the remaining suspending bonds in the area, thereby enhancing the treatment effect on the area; meanwhile, since the process conditions of the treatment operations are the same, the action range of each of the treatment operations and the intensity thereof are predicable, thereby facilitating the accurate regulation and control of the treatment effect on the surface of the tungsten material layer.

Of course, the process conditions of the treatment operations may also be different, and the treatment effect of each of the treatment operations can be gradually weakened by adjusting one or more process parameters. Optionally, the treatment time of each of the treatment operations is gradually reduced. Exemplarily, the process condition of the first treatment operation are: 300° C., 5 Torr, 10 sccm and 15 seconds, and then Ar purging is performed; the process conditions of the second treatment operation are: 300° C., 5 Torr, 10 sccm and 5 seconds, and then Ar purging is performed; . . . ; and the process conditions of the Nth treatment operation are: 300° C., 5 Torr, 10 sccm and 3 seconds, and then Ar purging is performed.

In other embodiments, the treatment effect can be adjusted by gradually increasing the pressure of each of the treatment operations and/or gradually reducing the gas flow rate. The treatment effect of each of the treatment operations is gradually weakened with the increased pressure or the reduced the gas flow rate. The etching and activating effect on the tungsten material layer is continuously enhanced by adjusting the process condition of each of the treatment operations, and the declining effect of each of the treatment operations will not enhance the treatment intensity of the whole treatment step on the tungsten material layer.

It should be noted that the treatment effect of each of the treatment operations is not limited to the declining trend, and can also be designed according to the actual product requirements, which will not be limited by the present invention. For example, due to the steric effect of gas diffusion and the characteristic of the free radical of the treatment gas, the etching effect of the treatment gas on the surface of the tungsten material layer of the recessed structure 102 and the density of the generated surface bond is gradually weakened from the top of the recessed structure 102 downward, that is, the tungsten material layer at the side wall of the recessed structure 102 is less affected by the treatment gas with the increase of the depth. However, in some application scenarios, it is necessary to extend the range of the tungsten growth inhibition area 201 of the tungsten material layer at the side wall downward, so that during the subsequent deposition of the tungsten material layer, the tungsten material layer preferentially grows on the middle lower layer of the recessed structure 102 and will not be attached to the tungsten material layer at the side wall, thereby avoiding the premature closing of the top opening of the recessed structure 102. For the above application requirement, the first treatment operation can be used to preliminarily etch the tungsten material layer of the recessed structure 102 and generate the surface bond. It can be seen from the above that the etching of the treatment gas can enlarge the opening of the recessed structure 102, which provides a convenient condition for the treatment gas to enter the recessed structure 102 subsequently. The gas flow rate of the treatment gas can be selectively increased and/or the treatment pressure can be reduced and/or the treatment time can be prolonged in the subsequent treatment operation, so that the depth of etching and activating the tungsten material layer at the side wall of the recessed structure 102 by the treatment gas can be enlarged, thereby extending the range of the tungsten growth inhibition area 201 downward.

It can be seen from the above that the tungsten material layer in the semiconductor substrate 100 is prepared by the method for depositing the tungsten in the high-aspect-ratio structure, so that the internal space of the recessed structure 102 can be filled with the tungsten material layer from bottom to top; and the positions of the seams 205 in the internal space are low and the seams 205 are small, thereby facilitating the formation of the low-resistance path from the bottom of the recessed structure 102 to the top of the recessed structure 102.

Further, the center of the tungsten material layer filled in the recessed structure 102 in the semiconductor substrate 100 includes a plurality of seams 205 distributed up and down, and the height of each seam 205 is less than ¼ of the height of the recessed structure 102.

In conclusion, in the method for depositing the tungsten in the high-aspect-ratio structure, and the semiconductor substrate 100 thereof provided by the present invention, the tungsten material is deposited in the recessed structure 102 with the aspect ratio greater than 50, the method combines the first deposition step, the treatment step and the second deposition step, the tungsten material layer formed in the first deposition step is treated by the treatment gas in the treatment step, and the surface of the tungsten material layer can be etched by the free radical containing fluorine/chlorine in the treatment gas, so that the size of the top opening of the recessed structure 102 can be increased, and the subsequent filling of the tungsten material can be facilitated; meanwhile, the free radical at least containing one of carbon, sulfur, nitrogen, hydrogen or oxygen in the treatment gas forms the surface bond on the surface of the tungsten material layer close to the opening of the recessed structure 102, the area where the surface bond is formed will delay the growth of the tungsten material layer in the second deposition step, the tungsten growth inhibition area 201 is formed on the side wall of the recessed structure 102, the depth of the active free radical entering the recessed structure 102 can be controlled by controlling the flow rate range of the treatment gas in the treatment step to 1-200 sccm, and then the depth of the tungsten growth inhibition area 201 can be controlled. The premature closing of the top opening of the recessed structure 102 is further avoided, the seams 205 in the recessed structure 102 can be moved downward and narrowed, and the seams 205 can be prevented from being exposed during a subsequent CMP treatment process, thereby facilitating prolonging the service life of the semiconductor substrate 100 and improving the electrical performance of the semiconductor substrate. On the other hand, according to the method, a new observable thin film layer will not be formed in the tungsten material layer, thereby avoiding the adverse effect on the semiconductor substrate 100.

Further, the treatment step in the method can act on the tungsten nucleation layer 202, so that the tungsten bulk layer 203 tends to be deposited on a middle lower part of the internal space of the recessed structure 102 subsequently, thereby further ensuring the downward movement and narrowing of the seams 205 in the recessed structure 102.

Further, the method adopts a mode of performing the plurality of steps repeatedly, so that a tungsten section is filled and grown in the recessed structure 102, a large seam 205 in the recessed structure 102 is divided into a plurality of small seams 205, and the seams 205 can be further moved downward in the recessed structure 102, thereby preventing the seams 205 from being exposed in the subsequent CMP treatment process, and preventing the tungsten material layer in the recessed structure 102 from being eroded.

Although the content of the present invention has been described in detail through the aforementioned preferred embodiments, it should be recognized that the above description should not be considered as limiting the present invention. Various modifications and alternatives to the present invention will become apparent to those skilled in the art upon reading the foregoing disclosure. Accordingly, the protection scope of the present invention shall be limited by the appended claims.

1. A method for depositing tungsten in a high-aspect-ratio structure, wherein the high-aspect-ratio structure is a recessed structure recessed downward from a surface of a substrate, the aspect ratio of the recessed structure is greater than 50:1, and the method for depositing the tungsten comprises:
a first deposition step: depositing a tungsten material layer with a first thickness on a side wall and at the bottom of the recessed structure, the first thickness being 10-500 Angstroms;
a treatment step: introducing a treatment gas to the surface of the substrate, the treatment gas comprising a free radical containing fluorine/chlorine and a free radical at least containing one of carbon, sulfur, nitrogen, hydrogen or oxygen, the flow rate range of the treatment gas being 1-200 sccm, and the free radical at least containing one of carbon, sulfur, nitrogen, hydrogen or oxygen and at least part area of the tungsten material layer deposited on the side wall of the recessed structure forming a tungsten growth inhibition area; and
a second deposition step: depositing a tungsten material layer with a second thickness in the recessed structure treated in the treatment step, so that at least part area of the recessed structure is filled with the tungsten.

2. The method for depositing tungsten in a high-aspect-ratio structure according to claim 1, wherein
the tungsten growth inhibition area comprises an area extending from the surface of the substrate to the bottom of the recessed structure along the side wall of the recessed structure by a first depth, the first depth being less than or equal to ⅔ of the depth of the recessed structure.

3. The method for depositing tungsten in a high-aspect-ratio structure according to claim 2, wherein
the treatment gas etches the tungsten material layer with a second depth on a side wall of the top of the recessed structure through the free radical containing fluorine/chlorine, the second depth being less than or equal to the first depth.

4. The method for depositing tungsten in a high-aspect-ratio structure according to claim 1, wherein
the time range of the treatment step is 0-180 seconds.

5. The method for depositing tungsten in a high-aspect-ratio structure according to claim 1, wherein
the time range of the treatment step is 0-40 seconds.

6. The method for depositing tungsten in a high-aspect-ratio structure according to claim 1, wherein
the tungsten material layer filled in the second deposition step comprises a long strip-shaped pore inside, the height of the long strip-shaped pore being less than 60% of the depth of the recessed structure.

7. The method for depositing tungsten in a high-aspect-ratio structure according to claim 1, wherein
the first deposition step adopts an atom-like layer deposition process or a pulse deposition process or a combination of an atom-like layer deposition process/pulse deposition process and a chemical vapor deposition process; and
the second deposition step adopts the chemical vapor deposition process.

8. The method for depositing tungsten in a high-aspect-ratio structure according to claim 1, wherein
in the first deposition step, a tungsten nucleation layer or a tungsten nucleation layer and part of a tungsten bulk layer is/are deposited.

9. The method for depositing tungsten in a high-aspect-ratio structure according to claim 1, further comprising:
repeatedly performing the treatment step and the second deposition step, so that more parts of the recessed structure are filled.

10. The method for depositing tungsten in a high-aspect-ratio structure according to claim 9, wherein
the treatment gas flow rate or treatment time in the current treatment step is less than or shorter than the treatment gas flow rate or treatment time in the previous treatment step.

11. The method for depositing tungsten in a high-aspect-ratio structure according to claim 9, wherein
the process time of the current second deposition step is shorter than the process time of the previous second deposition step.

12. The method for depositing tungsten in a high-aspect-ratio structure according to claim 9, wherein
the process time of the last second deposition step is longer than the process time of the previous second deposition step.

13. The method for depositing tungsten in a high-aspect-ratio structure according to claim 9, wherein
when the treatment step and the second deposition step are performed repeatedly, the method further comprises performing the first deposition step after at least one second deposition step.

14. The method for depositing tungsten in a high-aspect-ratio structure according to claim 1, wherein
the treatment step comprises a plurality of alternating treatment substeps and purification substeps, the treatment gas is introduced into the treatment substeps, and an inert gas is introduced into the purification substeps.

15. The method for depositing tungsten in a high-aspect-ratio structure according to claim 14, wherein
the process time of the treatment substeps or the purification substeps is shorter than 60 seconds.

16. The method for depositing tungsten in a high-aspect-ratio structure according to claim 14, wherein
the process time of the treatment substeps or the purification substeps is shorter than 10 seconds.

17. The method for depositing tungsten in a high-aspect-ratio structure according to claim 1, wherein
the treatment gas is selected from one of SF6, NF3, HCl, fluorocarbon, hydrofluorocarbon, oxyfluoride, chlorocarbon, chlorohydrocarbon and oxychloride, or a mixed gas thereof.

18. The method for depositing tungsten in a high-aspect-ratio structure according to claim 1, wherein
the treatment step comprises a plurality of treatment operations, and the treatment effect of each of the treatment operations is adjustable.

19. The method for depositing tungsten in a high-aspect-ratio structure according to claim 18, wherein
the process conditions of the treatment operations are the same;
or the treatment time of each of the treatment operations is gradually reduced and/or the pressure of each of the treatment operations is gradually increased and/or the gas flow rate is gradually reduced.

20. The method for depositing tungsten in a high-aspect-ratio structure according to claim 1, wherein
the pressure range of the first deposition step is 1-30 Torr, and the pressure range of the second deposition step is 5-100 Torr.

21. A method for depositing tungsten in a high-aspect-ratio structure, wherein the high-aspect-ratio structure is a recessed structure recessed downward from a surface of a substrate, the aspect ratio of the recessed structure is greater than 50:1, and the method for depositing the tungsten comprises:
a first deposition step: depositing tungsten nucleation layers on a side wall and at the bottom of the recessed structure;
a treatment step: introducing a treatment gas to the surface of the substrate, the treatment gas comprising a free radical containing fluorine/chlorine and a free radical at least containing one of carbon, sulfur, nitrogen, hydrogen or oxygen, the flow rate range of the treatment gas being 1-200 sccm, and the free radical at least containing one of carbon, sulfur, nitrogen, hydrogen or oxygen and at least part area of the tungsten nucleation layer deposited on the side wall of the recessed structure forming a tungsten growth inhibition area; and
a second deposition step: depositing a tungsten material layer in the recessed structure treated in the treatment step, so that at least a part recessed structure is filled with the tungsten.

22. The method for depositing tungsten in a high-aspect-ratio structure according to claim 21, wherein
the first deposition step adopts an atom-like layer deposition process and/or a pulse deposition process; and the second deposition step adopts a chemical vapor deposition process.

23. The method for depositing tungsten in a high-aspect-ratio structure according to claim 21, wherein
the thickness of the tungsten nucleation layer deposited in the first deposition step is less than 150 Angstroms.

24. The method for depositing tungsten in a high-aspect-ratio structure according to claim 21, wherein
the treatment step comprises a plurality of alternating treatment substeps and purification substeps, the treatment gas is introduced into the treatment substeps, and an inert gas is introduced into the purification substeps.

25. The method for depositing tungsten in a high-aspect-ratio structure according to claim 21, wherein
the time range of the treatment step is 0-30 seconds.

26. The method for depositing tungsten in a high-aspect-ratio structure according to claim 21, wherein
the treatment gas is selected from one of SF6, NF3, HCl, fluorocarbon, hydrofluorocarbon, oxyfluoride, chlorocarbon, chlorohydrocarbon and oxychloride, or a mixed gas thereof.

27. The method for depositing tungsten in a high-aspect-ratio structure according to claim 21, further comprising:
repeatedly performing the treatment step and the second deposition step, so that more parts of the recessed structure are filled.

28. The method for depositing tungsten in a high-aspect-ratio structure according to claim 27, wherein
the treatment gas flow rate or treatment time in the current treatment step is less than or shorter than the treatment gas flow rate or treatment time in the previous treatment step; and/or the process time of the current second deposition step is shorter than the process time of the previous second deposition step.

29. The method for depositing tungsten in a high-aspect-ratio structure according to claim 27, wherein
the process time of the last second deposition step is longer than the process time of the previous second deposition step.

30. The method for depositing tungsten in a high-aspect-ratio structure according to claim 27, wherein
when the treatment step and the second deposition step are performed repeatedly, the method further comprises performing the first deposition step after at least one second deposition step.

31. A semiconductor substrate, comprising a material layer on a surface, wherein
a recessed structure with an aspect ratio greater than 50 is arranged on the material layer, a side wall and a bottom wall of the recessed structure comprise barrier layers, the internal space of the recessed structure surrounded by the barrier layers is filled with a tungsten material layer from the bottom to the top so as to form a low-resistance path from the bottom of the recessed structure to the top of the recessed structure, and the tungsten material layer is prepared by the method for depositing tungsten in a high-aspect-ratio structure according to claim 1.

32. The semiconductor substrate according to claim 31, wherein
a plurality of seams that are mutually separated and distributed up and down are formed inside the tungsten material layer, and the height of each of the seams is less than ¼ of the height of the recessed structure.

33. A semiconductor substrate, comprising a material layer on a surface, wherein
a recessed structure with an aspect ratio greater than 50 is arranged on the material layer, a side wall and a bottom wall of the recessed structure comprise barrier layers, the internal space of the recessed structure surrounded by the barrier layers is filled with a tungsten material layer from the bottom to the top so as to form a low-resistance path from the bottom of the recessed structure to the top of the recessed structure, a plurality of seams that are mutually separated and distributed up and down are formed inside the tungsten material layer, and the height of each of the seams is less than ¼ of the height of the recessed structure.
